(19) United States
(12) Patent Application Publication
(10) Pub. No.: US 2026/0113990 A1
(43) Pub. Date: Apr. 23, 2026

(54) MULTI-LEVEL EPITAXIAL GAN SUBSTRATE AND FUNNEL GAN FET STRUCTURE

(71) Applicant: Alithia Power Inc., Raleigh, NC (US)

(72) Inventors: Cristofer Ugolini, Raleigh, NC (US); Allen Hanson, Cary, NC (US)

(73) Assignee: Alithia Power Inc., Raleigh, NC (US)

(21) Appl. No.: 19/358,145

(22) Filed: Oct. 14, 2025

Related U.S. Application Data
(60) Provisional application No. 63/708,645, filed on Oct. 17, 2024.

(51) Int. Cl. H10D 30/83; H01L 21/02; H10D 30/01; H10D 62/17; H10D 62/60; H10D 62/85

(52) U.S. Cl. CPC H10D 30/831; H10D 30/0515; H10D 62/328; H10D 62/343; H10P 14/22; H10P 14/3416; H10D 62/60; H10D 62/8503

(57) ABSTRACT

A method includes providing a two-level gallium nitride (GaN) epitaxial substrate comprising a first GaN drift layer characterized by a first doping concentration and a second GaN drift layer disposed on the first GaN drift layer and characterized by a second doping concentration higher than the first doping concentration and forming a plurality of pedestals in the second GaN drift layer. Each of the plurality of pedestals is laterally separated by one of a plurality of funnels. The method also includes performing a channel regrowth process to regrow a plurality of n-type GaN channels, each disposed in one of the plurality of funnels, and performing a gate regrowth process to regrow p-type GaN. The method further includes patterning the p-type GaN to form a plurality of p-type GaN gates disposed in one of the plurality of n-type GaN channels, and forming source contacts, gate contacts, and a drain contact.

### CROSS-REFERENCES TO RELATED APPLICATIONS

This application claims priority to U.S. Provisional Patent Application No. 63/708,645, filed on Oct. 17, 2024, entitled “Multi-Level Epitaxial GaN Substrate and Funnel GaN FET Structure,” the disclosure of which is hereby incorporated by reference in its entirety for all purposes.

### BACKGROUND OF THE INVENTION

Gallium nitride (GaN) is a wide bandgap semiconductor material known for its superior electrical and thermal properties compared to traditional silicon-based semiconductors. With a bandgap of about 3.4 eV, GaN can operate at higher voltages, temperatures, and frequencies, making it ideal for high-power and high-frequency applications. GaN was crucial in advancing the development of light-emitting diodes (LEDs), where it has enabled the production of efficient blue and white LEDs, revolutionizing the lighting industry. Moreover, the high electron mobility and saturation velocity of GaN make it an excellent choice for high-frequency and high-power transistors used in radio frequency (RF) and microwave applications and for power conversion.

Due to the large critical field of GaN, the short carrier lifetime, and the high carrier mobility, GaN-based devices are increasingly used in applications such as power converters, inverters for electric vehicles, and wireless charging systems, where their efficiency and compact size offer significant benefits over silicon-based technologies. Overall, gallium nitride is a game-changing material in the semiconductor industry, driving advancements in energy efficiency and performance across a wide range of applications.

Despite the progress made in the field of GaN devices, there is a need in the art for improved GaN-based semiconductor devices and improved methods for fabricating the same.

### BRIEF DESCRIPTION OF THE DRAWINGS

FIG. 1 is a simplified flowchart illustrating a method for making a two-level GaN epitaxial substrate according to an embodiment of the present disclosure.

FIG. 2 is a cross-sectional diagram of a GaN substrate according to an embodiment of the present invention.

FIG. 3 is a cross-sectional diagram of a GaN substrate and a first GaN drift layer according to an embodiment of the present invention.

FIG. 4 is a cross-sectional diagram of a GaN substrate, a first GaN drift layer, and a second GaN drift layer according to an embodiment of the present invention.

FIG. 5 is a simplified flowchart illustrating a method for making a funnel GaN FET structure according to an embodiment of the present disclosure.

FIG. 6 is a cross-sectional diagram of a GaN substrate, a first GaN drift layer, and a second GaN drift layer according to an embodiment of the present invention.

FIG. 7 is a cross-sectional diagram of pedestals formed in a second GaN drift layer according to an embodiment of the present invention.

FIG. 8A is a cross-sectional diagram illustrating a first portion of the channel regrowth process according to an embodiment of the present invention.

FIGS. 8B-8G illustrate the initial and final shapes of the regrown GaN for various process conditions according to embodiments of the present invention.

FIGS. 9A-9C are cross-sectional diagram illustrating regrown channel shapes according to an embodiment of the present invention.

FIGS. 10A-10C are cross-sectional diagrams illustrating a first portion of the p-type GaN regrowth process according to embodiments of the present invention.

FIGS. 11A-11C are cross-sectional diagrams illustrating different final p-type GaN shapes according to embodiments of the present invention.

FIGS. 12A-12C are cross-sectional diagrams illustrating gate shapes according to embodiments of the present invention.

FIGS. 13A-13C are cross-sectional diagrams illustrating ohmic contacts according to embodiments of the present invention.

FIGS. 14A-14C are simplified perspective diagrams illustrated various designs for achieving different operational modes according to embodiments of the present invention.

FIGS. 15A and 15B are simplified cross sectional diagrams illustrating operation of D-mode and e-mode JFET architectures, respectively, according to an embodiment of the present invention.

### DETAILED DESCRIPTION OF SPECIFIC EMBODIMENTS

In power electronics, a “killer defect” is any abnormality in the wafer that causes premature breakdown or other parametric or catastrophic failures of the devices fabricated on the wafer. Aside from disabling or destroying the device, the density of killer defects influences many different parts of the manufacturing value chain. While other materials like silicon (Si) and silicon carbide (SiC) have had decades of research dedicated to studying and decreasing the density of killer defects, single crystal GaN is still at an early stage in this development area. Embodiments of the present invention address technical problems faced by conventional vertical GaN FETs. More particularly, embodiments of the present invention provide a novel two-level GaN epitaxial substrate (or two-level GaN epitaxial stack) and a novel funnel GaN FET structure. Other embodiments provide methods of fabricating a novel two-level GaN epitaxial substrate (or two-level GaN epitaxial stack) and/or a novel funnel GaN FET structure.

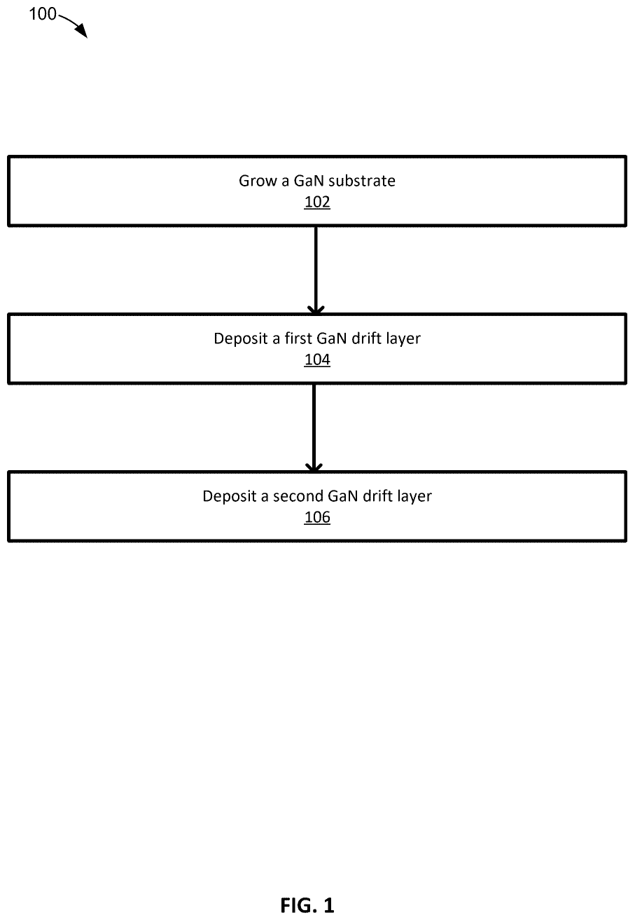

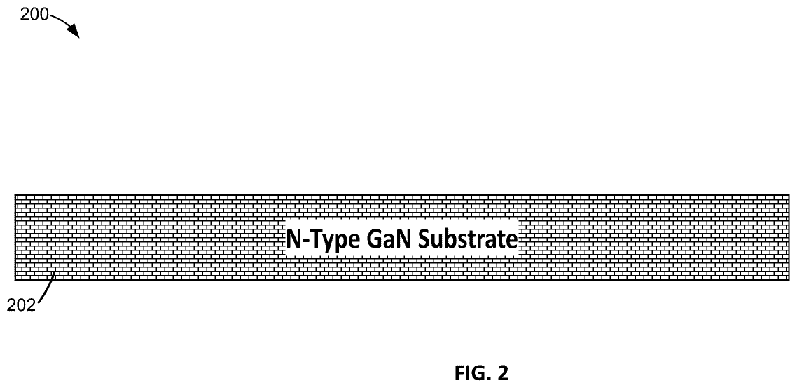

FIG. 1 is a simplified flowchart illustrating a method for making a two-level GaN epitaxial substrate according to an embodiment of the present disclosure. FIGS. 2-4 are cross-sectional diagrams illustrating a two-level GaN epitaxial substrate during various stages of fabrication according to an embodiment of the present disclosure.

As described more fully herein, the method 100 includes growing a GaN substrate (102). In some embodiments, the GaN substrate is a base bulk GaN substrate. In one embodiment, the GaN substrate is grown using an ammonothermal growth process. In one embodiment, the GaN substrate is an N-type GaN substrate 202, as shown in FIG. 2.

Ammonothermal growth is a crystal growth technique used to produce high-quality GaN crystals by utilizing supercritical ammonia as a solvent. Unlike the hydrothermal growth process, which operates with water, the ammonothermal growth process operates with ammonia. In an ammonothermal reactor, GaN source material is dissolved in supercritical ammonia at high temperatures and pressures. The reactor is designed with a temperature gradient, where the source material dissolves in the hotter region and subsequently crystallizes in the cooler region onto seed crystals, gradually forming large, high-purity GaN crystals.

Ammonothermally grown GaN substrates or wafers are highly valued for their superior crystalline quality and low defect densities, making them ideal for high-performance semiconductor applications. These GaN wafers can serve as native substrates for further epitaxial growth, which helps in mitigating lattice mismatch issues that commonly arise when GaN is grown on non-native substrates like sapphire or silicon carbide. The high-quality GaN crystals produced via the ammonothermal method are useful for manufacturing advanced electronic and optoelectronic devices such as high-electron-mobility transistors (HEMTs), laser diodes, and LEDs. The scalability of the ammonothermal growth process also enables commercial production, potentially lowering the cost and increasing the availability of high-quality GaN substrates.

Due to these benefits of ammonothermal growth, the N-type GaN substrate 202 grown using the ammonothermal growth process exhibits world-record dislocation density, crystalline quality, and electrical conductivity. These substrates allow for making larger chip sizes, higher process yields, better efficiency, among other performance measures.

FIGS. 2-4 are cross-sectional diagrams illustrating a two-level GaN epitaxial substrate during various stages of fabrication according to an embodiment of the present disclosure.

FIG. 2 is a cross-sectional diagram 200 of a GaN substrate according to an embodiment of the present invention. As shown in FIG. 2, the thickness of the n-type GaN substrate 202 is chosen according to the need to prevent handling and growth issues such as cracking and machine transfer between processes. In one embodiment, the thickness is larger than 200 μm for a two-inch wafer, larger than 450 μm for a four-inch wafer, and larger than 550 μm for a six-inch wafer. The doping can be either n-type or p-type. In the example shown in FIG. 2, the resistivity is lower than 3 mΩ cm. In the example shown in FIG. 2, the dislocation density is lower than 5×10⁵ cm⁻². It should be understood that these ranges are exemplary rather than limiting.

The method 100 also includes depositing a first GaN drift layer (104). In one embodiment, the first GaN drift layer is deposited using a hydride vapor phase epitaxy (HVPE) process.

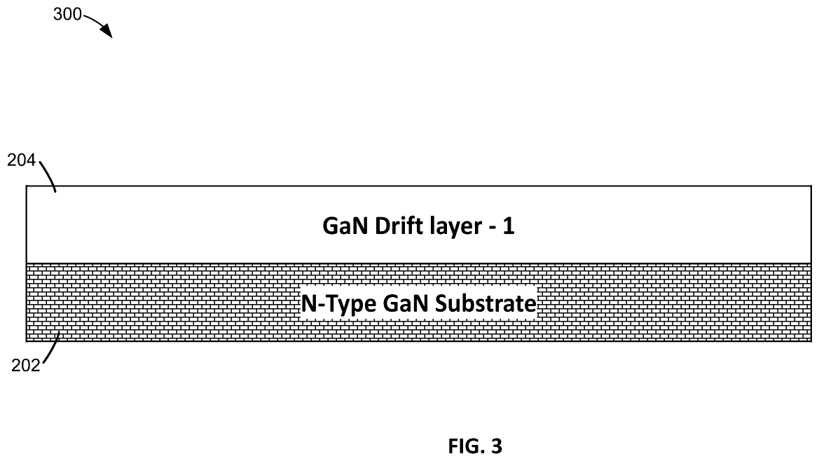

FIG. 3 is a cross-sectional diagram 300 of a GaN substrate and a first GaN drift layer according to an embodiment of the present invention. In the example shown in FIG. 3, the thickness of the first GaN drift 204 layer is between 3 μm and 150 μm.

The HVPE process is a technique primarily used in the semiconductor industry for the growth of high-quality crystalline layers. The HVPE process is notable for producing materials like GaN and other III-V semiconductors, which are utilized in various high-power and high-frequency electronic devices, as well as optoelectronic devices such as LEDs and laser diodes.

Source materials used in HVPE includes hydrides and carrier gas. Hydrides are typically used as the source of group III and group V elements. For instance, gallium chloride (GaCl) is often used as the source for gallium, while ammonia (NH₃) provides nitrogen in GaN growth. Hydrogen (H₂) or nitrogen (N₂) is often used as a carrier gas to transport the hydrides to the substrate. The HVPE process typically takes place in a reactor in which the substrate is placed, and the reactor must withstand high temperatures, typically in the range of 600 to 1100° C., depending on the material being grown. The precursor gases (e.g., hydrides) decompose or react at high temperatures to form the desired material on the substrate. For GaN, the reaction generally involves GaCl reacting with NH₃ to deposit GaN on the substrate surface.

The substrate is cleaned and prepared to ensure good quality epitaxial growth. Hydride gases are then introduced into the reactor. During GaN growth, HCl gas reacts with liquid gallium to form GaCl, which is then transported to the substrate. At the substrate surface, the chemical reactions take place. For GaN, GaCl reacts with NH₃, depositing GaN on the substrate and releasing byproducts like HCl. The growth rate and quality of the epitaxial layer are controlled by adjusting parameters such as temperature, flow rates of the gases, and reactor pressure. After the desired thickness of the epitaxial layer is achieved, the substrate is cooled down and removed from the reactor.

Using HVPE to make the drift layer has the following advantages. HVPE can achieve significantly higher growth rates compared to other epitaxial methods like Metal-Organic Chemical Vapor Deposition (MOCVD). In the example shown in FIG. 3, the first GaN drift layer 204 is deposited at a growth rate between 10 to 50 μm per hour.

HVPE also produces high-purity and high-crystallinity layers, beneficial for device performance. The carbon impurity is below the detection limit of secondary ion mass spectrometry (SIMS), which is very difficult to achieve by MOCVD. In a MOCVD process, carbon is present in the chamber coming from the precursors utilized, e.g., trimethyl gallium. Carbon adheres to and is introduced into the lattice of the grown GaN. Carbon acts as a dopant in GaN, traditionally taking on p-type behavior under traditional growth process conditions. As a p-type dopant, Carbon captures free carriers from the n-type dopant thus compensating the free carriers. Aside from changing the carrier concentration, carbon lowers the carrier mobility by introducing more scattering centers. In addition, in a MOCVD process, magnesium doping profile cannot be confined within an intended region of the grown layers due to diffusion at high temperature. Often times, this uncontrolled diffusion results in Mg moving into the channel region, degrading the properties of the junction, and hence the ability to gate to modulate the carrier in the channel region well. Methods such as MBE are better suited for achieving such doping profiles in GaN owing to the lower growth temperatures inherent to the method.

In some examples, oxygen impurity is below 1×10¹⁶ cm⁻³; carbon impurity is below 1×10¹⁶ cm⁻³; iron impurity is below 1×10¹⁶ cm⁻³. The HVPE process is suitable for large-area substrates, making it economically viable for mass production. These impurities impact the device performance. It should be noted that the low carbon impurity levels provided by embodiments of the present invention enables performance not available using conventional techniques. For instance, since carbon acts as an p-type donor on GaN, doping with silicon at a level of 1×10¹⁶ cm⁻³ with a background carbon impurity level of 1×10¹⁶ cm⁻³ will result in a low concentration of carriers and degraded carrier mobility. While the low carrier concentration created by the additive properties of these two dopants seems beneficial for high voltage breakdown, the process is largely unstable and difficult to replicate leading to widely varying critical fields, unstable device performance, and low manufacturing process yields. Because embodiments of the present invention provide carbon impurity levels less than 1×10¹⁶ cm⁻³, controllable and repeatable doping at levels lower than 1×10¹⁶ cm⁻³ can be achieved and sustained. As will become evident later, the width of the drift layer is inversely proportionate with the carrier density in the drift region. Lower carrier concentrations allow the channel to be much wider (i.e. larger features sizes). Larger feature sizes make it easier to use more traditional lithography devices, which increases process yield and improves manufacturability.

In some embodiments, a technology that provides substantial separation of the wafer from hot quartz materials within the reactor may be used, and it allows the background silicon level to drop below 4×10¹⁵ cm⁻³ so that residual silicon impurities can be mitigated. The net benefits of HVPE compared to MOCVD are a carrier mobility that is nearly two times higher, 40% higher throughput and lower costs, and higher process yields. In some examples, the electron mobility is higher than 1000 cm²/Vs; the carrier concentration is lower than 1×10¹⁷ cm⁻³; the doping concentration is between 2×10¹⁴ cm⁻³ and 1×10¹⁷ cm⁻³.

Additionally, the HVPE process may be modified to achieve a low supersaturation of gallium at the surface of the wafer. This allows the as-grown epitaxial surface to be atomically flat. In one example, the surface roughness Rz is lower than 1.5 nm (measured by AFM, at a 10-μm by 10-μm scan). In some embodiments, small volumes (<25% molar volume of total carrier gas) of hydrogen are used to improve the quality of the growth surface.

The method 100 further includes depositing additional layers, exemplified by a second GaN channel layer (106). The doping concentration of the second GaN channel layer can be higher than the doping concentration of the first GaN drift layer, thereby achieving a two-level doping profile in in the layers.

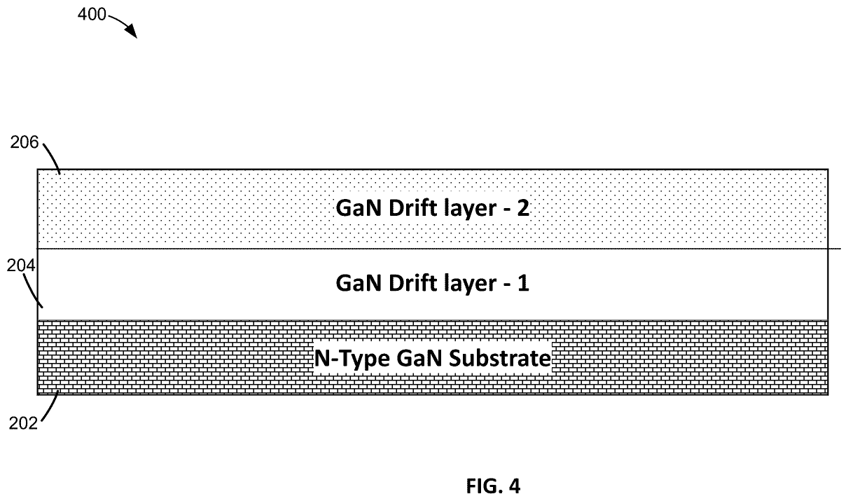

FIG. 4 is a cross-sectional diagram 400 of a GaN substrate, a first GaN drift layer, and a second GaN drift layer according to an embodiment of the present invention. Referring to FIG. 4, the first GaN drift layer 204 and the second GaN layer 206 are illustrated. The thickness of the first GaN drift layer 204 and the second GaN drift layer 206 can be between 5 μm and 150 μm. The doping concentration may also be graded from one level to another. In one example, the doping concentration of the second GaN layer 206 is 1×10¹⁶ cm⁻³ and the doping concentration of the first GaN drift layer 204 is 5×10¹⁵ cm⁻³. It should be understood that, in other embodiments, the doping concentration of the second GaN layer is the same as or lower than the doping concentration of the first GaN drift layer. Additional layers or graded doping regions may be subsequently added.

The inventors have determined that in some embodiments, it is beneficial to have the multi-level doping profile in order to form an appropriately doped channel layer while maintaining the lightly doped drift layer for supporting high voltage. Accordingly, a higher conductivity is achieved in the channel, and the on-resistance is lower for a higher blocking voltage enabled by the drift layer. In some examples, the on-resistance is 20% lower than singularly doped drift layers.

In the example shown in FIG. 4, the thickness of the first GaN drift layer 206 is between 3 μm and 150 μm. In some examples, the electron mobility is higher than 1000 cm²/Vs; the carrier concentration is lower than 1×10¹⁷ cm⁻³; the doping concentration is between 2×10¹⁴ cm⁻³ and 1×10¹⁷ cm⁻³. In some examples, oxygen impurity is below 1×10¹⁶ cm⁻³; carbon impurity is below 1×10¹⁶ cm⁻³; and iron impurity is below 1×10¹⁶ cm⁻³. In one example, the surface roughness R_{z} is lower than 1.5 nm (measured by AFM, at a 10-μm by 10-μm scan).

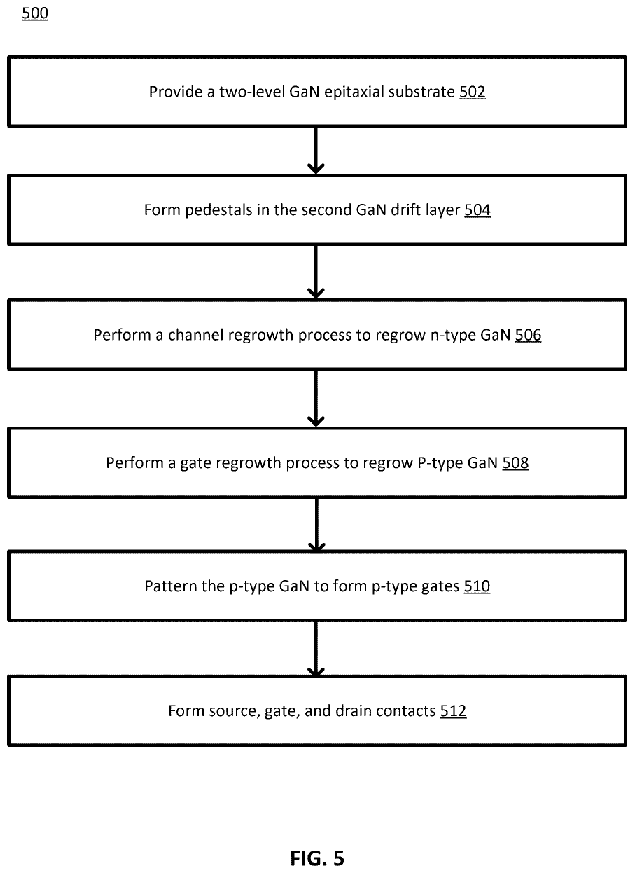

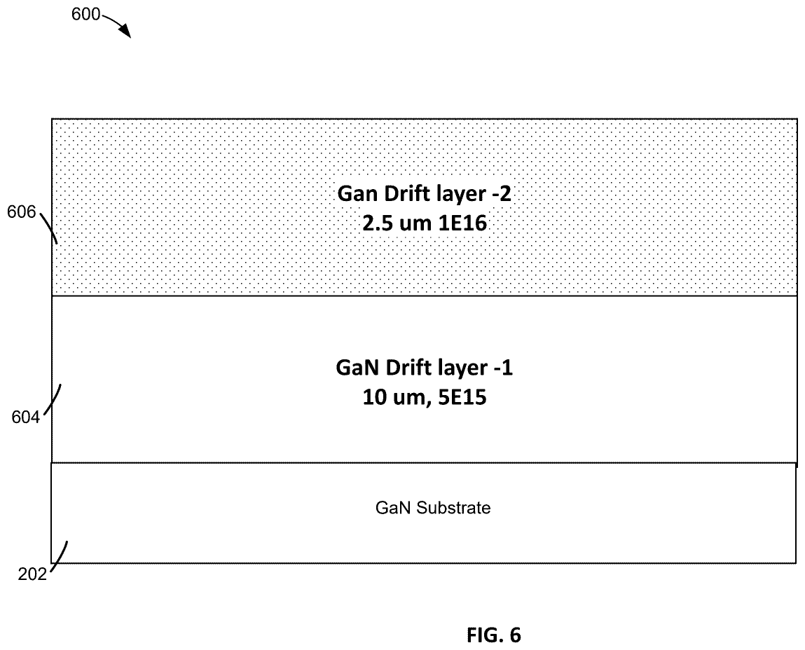

FIG. 5 is a simplified flowchart illustrating a method for making a funnel GaN FET structure according to an embodiment of the present disclosure. FIGS. 6-13 are cross-sectional diagrams illustrating funnel GaN FET structures during various stages of fabrication according to an embodiment of the present disclosure.

The method 500 includes providing a two-level GaN epitaxial substrate (502). In one embodiment, the two-level GaN epitaxial substrate is provided using the method 100 shown in FIG. 1.

FIG. 6 is a cross-sectional diagram of a GaN substrate, a first GaN drift layer, and a second GaN drift layer according to an embodiment of the present invention. In the example shown in FIG. 6, the two-level GaN epitaxial substrate 600 includes the GaN substrate 602, first GaN drift layer 604, and second GaN drift layer 606. In an embodiment, the thickness of the first GaN drift layer is 10 μm and the thickness of the second GaN drift layer is 2.5 μm. The doping concentration of the second GaN drift layer 206 can be 1×10¹⁶ cm⁻³, and the doping concentration of the first GaN drift layer 204 can be 5×10¹⁵ cm⁻³. In an embodiment, the two-level GaN epitaxial substrate 600 includes the n-type GaN substrate 202, the first GaN drift layer 204, and second GaN drift layer 206 shown in FIG. 2, but this is not required. One of ordinary skill in the art would recognize many variations, modifications, and alternatives.

The method 500 also includes forming pedestals in the first GaN drift layer (504).

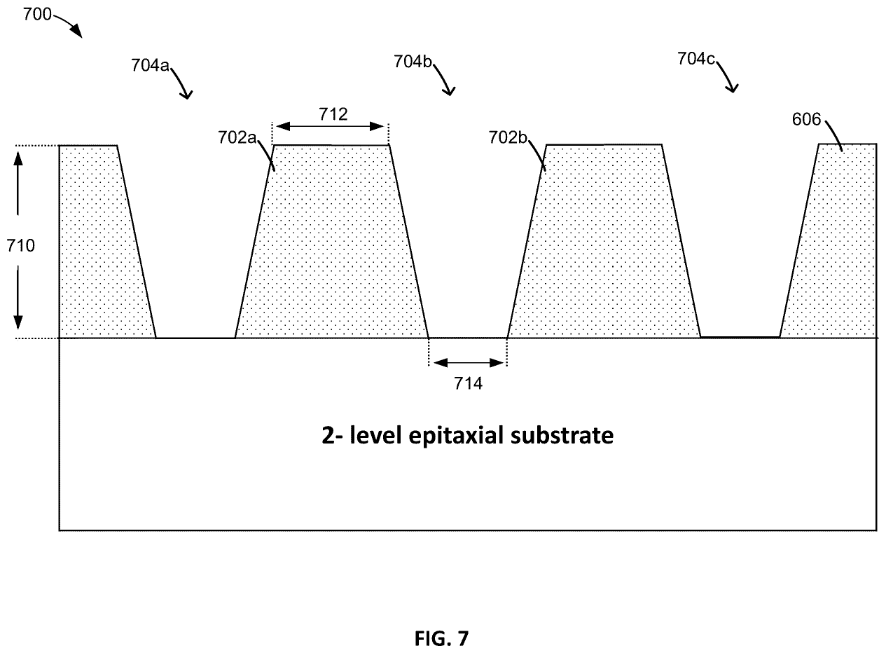

FIG. 7 is a cross-sectional diagram of pedestals formed in a second GaN drift layer according to an embodiment of the present invention. In the example shown in FIG. 7, pedestal 702a and pedestal 702b (collectively, pedestal set 702) are formed in the second GaN drift layer 606 illustrated in FIG. 6 of the two-level GaN epitaxial substrate 700 illustrated in FIG. 7.

Prior vertical GaN designs typically use a “trench and regrowth” process where trenches are etched into a planar drift layer, and then p-type GaN material is regrown into the trenches. The resulting side-by-side p-type GaN and drift layer constitute a gate and a channel if the dimensions and doping of the two layers are properly selected. This “trench and regrowth” approach has historically had many problems that have prohibited the creation of quality FETs. For example, after etching and regrowth processes, it is challenging to clean the interfaces to a sufficiently low concentration, and residual silicon or oxygen remains. The residual silicon or oxygen donors would hinder the ability of the regrown p-type GaN to form a sufficient depleted region when an electrical field is applied. There are also other issues that manifest during the trench formation. Most trenches are made with traditional etching processes like ICP which induce point defects like nitrogen vacancies or interstitials at the surface. These defects act to capture electrons or holes near the surface interface thus altering the carrier concentration and mobility. This, in turn, significantly alters the depletion region dimensions, deforming the channel and inhibiting the gate capabilities.

In contrast, the shape and size of the pedestal 702a and the pedestal 702b are uniquely designed. The pedestal 702a and the pedestal 702b are not intended to act as a side-by-side gate and channel. Instead, the pedestal 702a and the pedestal 702b are intended to act as nucleation structure to initiate growth of a series of layers that will eventually create a gate and a channel. The region 704b between the pedestal 702a and the pedestal 702b is not intended to be filled with p-type material to act as a gate. Instead, the sequenced regrowth that stems from the pedestal 702a and the pedestal 702b will create the gate and channel.

In the example shown in FIG. 7, the dimensions of pedestal features, i.e., the pedestal height 710, the pedestal width 712, and the pedestal gap 714 are selected so that the pedestal 702a and the pedestal 702b act as nucleation structures to initiate growth of a series of layers that will eventually create a gate and a channel. In one example, the pedestal height 710 of the pedestal 702) is between 1.5 μm and 5 μm. In another example, the pedestal height 710 is about 2.5 μm. In one example, the pedestal width 712 of the top surface of the pedestal (e.g., pedestal 702a) is between 0.5 μm and 2 μm. In another example, the pedestal width 712 is about 1.5 μm. In one example, the pedestal gap 714 (i.e., the lateral distance between the bottoms of two neighboring pedestals, for example, pedestal 702a and pedestal 702b) is between 1 μm and 2.5 μm. In another example, the pedestal gap 714 is about 1 μm.

Applicant has appreciated that the identified values of the pedestal height 710, the pedestal width 712, and the pedestal gap 714 will lead to final device architectures with high-performance transistor properties. A variety of semiconductor fabrication processes can be utilized to form the pedestals and the pedestal dimensions (i.e., the values of the pedestal height 710, the pedestal width 712, and the pedestal gap 714), including inductively coupled plasma (ICP) etching, reactive ion etching (RIE), atomic layer etching (ALE) or the like.

The pedestal etch depth varies with the desired electrical properties of the device. In some embodiments, the trench between the pedestals will include the entirety of the second ‘drift’ layer (w/channel doping) and land at or near the interface of the 1^{st}/2^{nd} (i.e., with drift doping). In some embodiments, the trench does not encompass the entire second drift layer, whereas as in other embodiments it extends into the first drift layer. One of ordinary skill in the art would recognize many variations, modifications, and alternatives.

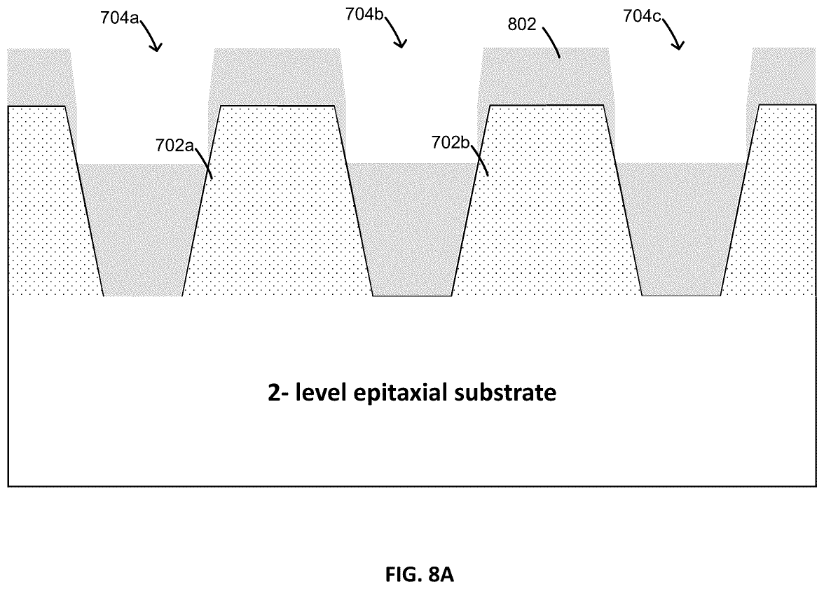

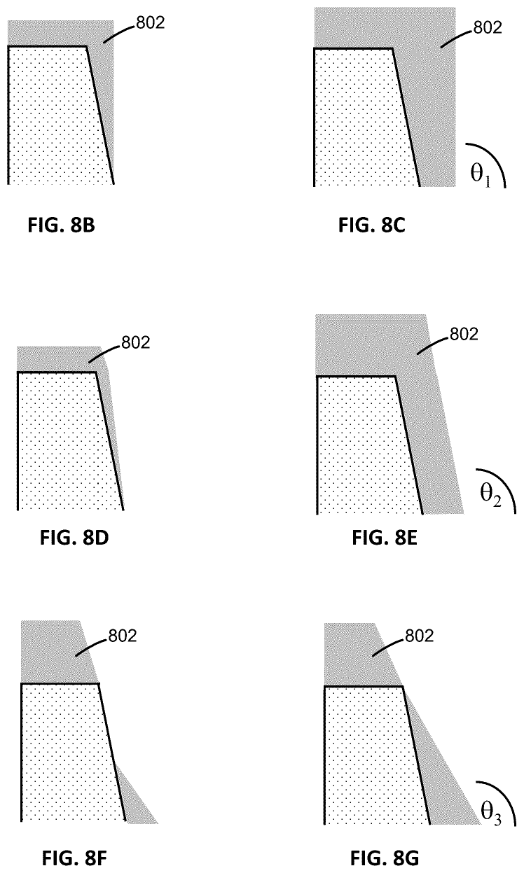

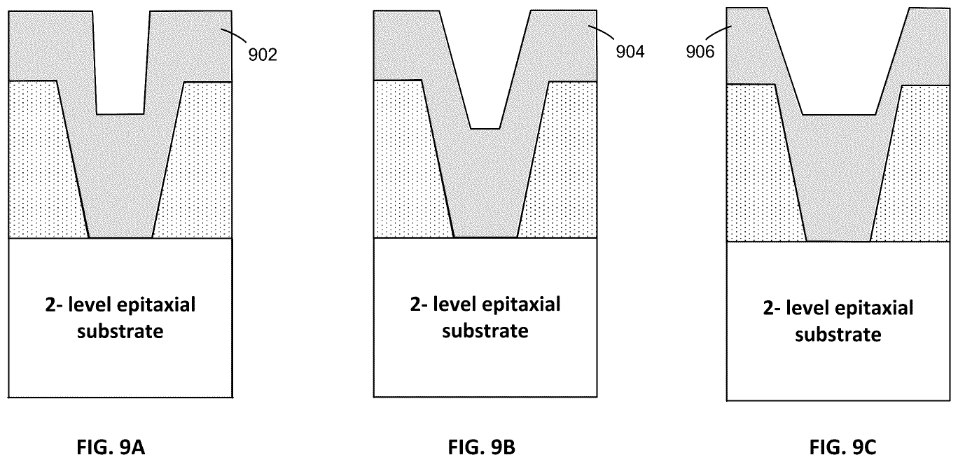

The method 500 further includes performing a channel regrowth process to grow n-type GaN (506). FIG. 8A is a cross-sectional diagram illustrating a first portion of the channel regrowth process according to an embodiment of the present invention. FIGS. 9A-9C illustrate different final channel shapes that can be achieved during the channel regrowth process.

Referring to FIG. 8A, in some embodiments, the regrown n-type GaN material 802 is regrown using molecular beam epitaxy (MBE) and has the same doping density as the second GaN drift layer 206 illustrated in FIG. 4. MBE processes are performed at a much lower temperature compared to MOCVD processes. Because of the kinetics and thermodynamics of the processes occurring during MBE, the regrowth inside region 704a, region 704b, and region 704c (collectively, set of regions 704) can steepen and narrow the openings of the set of regions 704. After a series of different growth layers, it is possible to create channels with variable width, height, and sharpness by changing the temperature, chemistry, and other process conditions of MBE. Thus, embodiments of the present invention can achieve a final channel thickness that is dependent on growth conditions rather than the resolution threshold of the lithography techniques. This is a differentiator in terms of design implementation since it is the first of its kind that creates the very small feature sizes utilized for an e-mode GaN JFET with the growth modalities of the deposition process and not the traditional lithography techniques. Because processes like MBE enable finer control over small thicknesses and doping gradients, the performance of devices made in such a way should exhibit better performance, yield, and long-term reliability to name a few. This will enable transistors to operate at voltages and power densities not currently realized in the state of the art.

In one implementation, the kinetic energy of the atoms is made very low and the n-type GaN 802 grows conformally, thus preserving the trench shape. If the kinetic energy is high, the n-type GaN 802 grows more laterally, thus planarizing the trench shape. Therefore, the resulting funnel shape is adjustable by changing parameters of the MBE process, depending on design requirements. Regions of n-type GaN 802 are also formed on the top surfaces of the pedestal 702a and the pedestal 702b. In some embodiments, the channel regrowth process and the gate regrowth process are performed in an MBE system at a growth temperature <800° C. and a V/III ratio <250 in order to produce reduced or minimal diffusion of the p-type dopant and conformal growth of the deposited material.

As such, channels of regrowth of n-type GaN 802 are formed out of the funnel between two neighboring pedestals 702, and regions of the n-type GaN 802 are formed on the top surfaces of the pedestals 702.

FIGS. 8B-8G illustrate the initial and final shapes of the regrown GaN for various process conditions according to embodiments of the present invention. In particular, FIG. 8B illustrates the initial shape and FIG. 8C illustrates the final shape for a low temperature process, FIG. 8D illustrates the initial shape and FIG. 8E illustrates the final shape for an intermediate temperature process, and FIG. 8F illustrates the initial shape and FIG. 8G illustrates the final shape for a high temperature process.

According to the Burton Cabrera and Framl model of crystal growth, if the temperature of the MBE growth process is high (e.g., 850° C.), the Ga adatoms have higher kinetic energy, which drives the supersaturation lower. The lower supersaturation decreases the terrace width of the mosaic, and the subsequent Ga adatoms preferentially deposit in a way to planarize the trench shape (illustrated as θ₃ in FIG. 8G). If the temperature of the MBE process is low (e.g., 700° C.) the Ga adatoms have lower kinetic energy which drives the supersaturation higher. This increases the terrace width of the mosaic, and the subsequent Ga adatoms preferentially deposit in a way that closes the shape of the trench. (illustrated as θ₁ in FIGS. 8B and 8C).

Since it is possible to planarize or close the trench by adjusting the temperature, one skilled in the art would understand that there exists a diverse set of process conditions such that θ can vary between a maximum and minimum angle defined by the following values. θ₃≤180 degrees, θ₁≥90 degrees, θ₁≤θ₂≤θ₃.

As stated before, the driving force for changing these growth modalities is the supersaturation of Ga adatoms. For processes such as MBE, it is possible to increase or decrease the supersaturation of the Ga adatoms with process parameters other than just the temperature of the growth environment. Changes in the overall pressure of the growth environment and stoichiometry of the incoming Ga and N precursors is another means to control the Ga supersaturation. One skilled in the art would understand how these parameters influence the supersaturation, and thus control the growth modalities.

Through regrowth of the n-type GaN on the custom trenches with a specific set of deposition process conditions, the problems associated with the regrowth interface discussed above can be solved. In the embodiments illustrated in FIGS. 8B-8G, θ₁=90°<θ₂<θ₃.

FIGS. 9A-9C are cross-sectional diagram illustrating regrown channel shapes according to an embodiment of the present invention. Referring to FIGS. 9A-9C, several different channel shapes can be produced during the channel regrowth process. In some embodiments, the channel regrowth process is an MBE process. The range of shapes for the regrown channel will allow for flexibility in on-resistance and gate control of the channel. At low temperatures, for example, MBE regrowth at temperatures ranging from 650° C. to 700° C., the regrown n-type GaN material 902 will be characterized by vertical sidewalls. Additionally, the low temperature shape illustrated in FIG. 9A will be characterized by very low on-resistance, but can also be characterized by less stable gate control. At high temperatures, for example, MBE regrowth at temperatures ranging from 750° C. to 800° C., the regrown n-type GaN material 906 will be characterized by sidewalls generally aligned with the sidewalls of the pedestals. Additionally, the high temperature shape illustrated in FIG. 9C will be characterized by high on-resistance, but can also be characterized by very stable gate control. At intermediate temperatures, for example, MBE regrowth at temperatures ranging from 700° C. to 750° C., the regrown n-type GaN material 904 will be characterized by sidewalls generally aligned with the sidewalls of the pedestals. Additionally, the high temperature shape illustrated in FIG. 9C will be characterized by medium on-resistance, but can also be characterized by medium gate control. Embodiments of the present invention provide a high level of design control during device fabrication, particularly during the development phase, using the spectrum of regrowth material shaping illustrated by the regrowth shapes shown in FIGS. 9A-9C.

The method 500 includes performing a gate regrowth process to regrow p-type GaN (508) that will subsequently be patterned to form the gates.

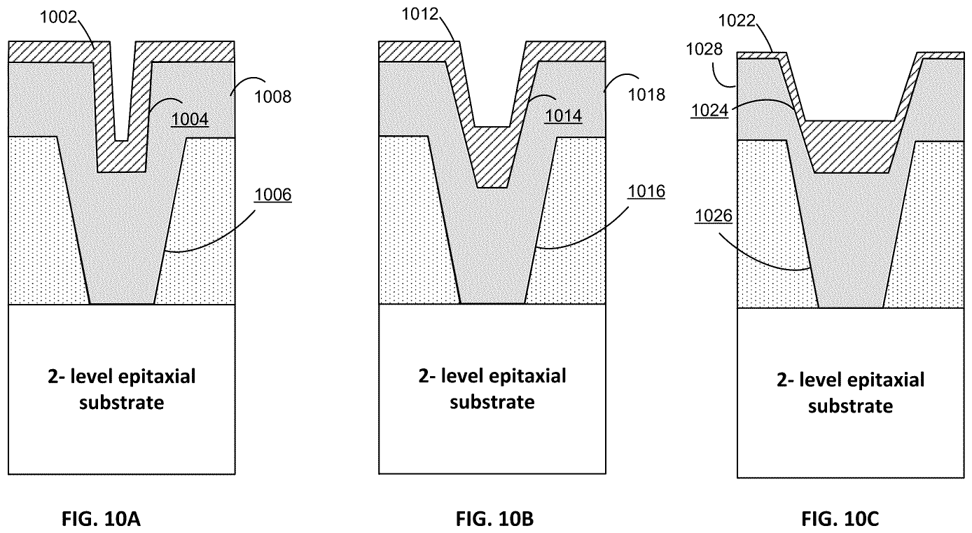

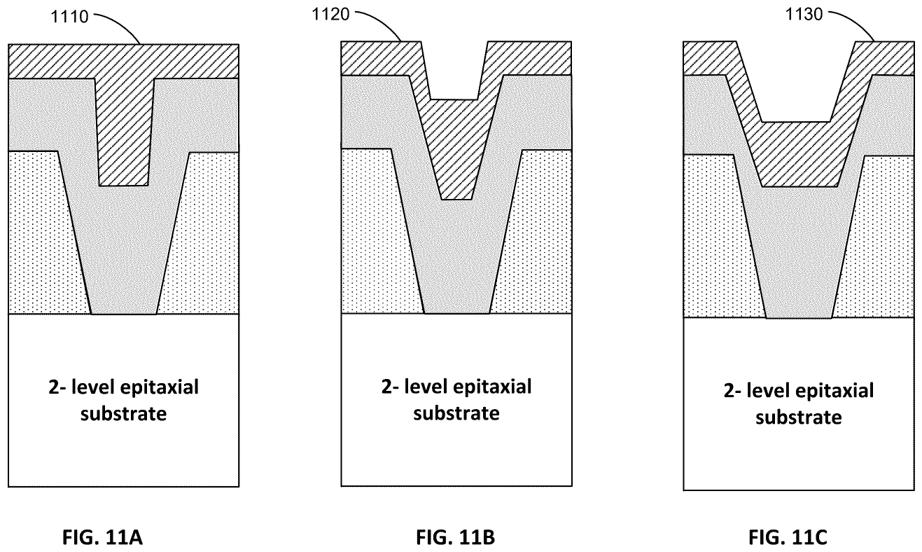

FIGS. 10A-10C are cross-sectional diagrams illustrating a first portion of the p-type GaN regrowth process according to embodiments of the present invention. FIGS. 11A-11C are cross-sectional diagrams illustrating different final p-type GaN shapes according to embodiments of the present invention. The regrowth shapes illustrated in FIGS. 11A-11C demonstrate the variety of regrowth shapes than can be achieved during the p-type GaN regrowth process utilizing the embodiments described herein.

With the pedestal design discussed herein, breaking vacuum is not needed to regrow the p-type GaN. At the beginning of the p-type GaN regrowth process as shown in FIGS. 10A-10C, a spectrum of possible shapes, including a vertical shape illustrated in FIG. 10A, an intermediate shape illustrated in FIG. 10B, and a conformal shape illustrated in FIG. 10C, can be produced during the p-type GaN regrowth processes performed in accordance with various embodiments.

Referring to FIG. 10A, the p-type GaN 1002 can have generally vertical sidewalls. Referring to FIG. 10B, the p-type GaN 1012 can have intermediate shaped sidewalls. Finally, referring to FIG. 10C, the p-type GaN 1022 can have sloped sidewalls. After the p-type GaN regrowth process is completed, as shown in FIGS. 11A-11C, the completion of the p-type GaN regrowth process will allow for multiple gate geometries depending on the initial pedestal shape and growth conditions of the n-type GaN (i.e., the channels) and the p-type GaN (i.e., the gates). As illustrated in FIG. 11A, p-type GaN 1110 can have a planar top surface. As illustrated in FIG. 11B, p-type GaN 1120 can be generally cylindrical with a small recess in the top surface. As illustrated in FIG. 11C, p-type GaN 1130 can increases in lateral width as a function of height and have a large recess in the top surface.

As illustrated in FIG. 10A, the interface 1004 between the n-type GaN 1008 forming the n-type channel and the p-type GaN 1002 forming the p-type gate is located at a distance from the initial regrowth interface 1006. Because the n-type GaN regrowth process shown in FIGS. 8A and 9A-9C and the p-type GaN regrowth process shown in FIGS. 10A-10C can be performed in an MBE chamber without breaking vacuum, a high quality interface, i.e. interface 1004, between the n-type channel and the p-type gate can be formed. The high quality interface present at interface 1004 is also spatially separated from the initial regrowth interface 1006, which can also be referred to as an etched surface, by the regrown n-type GaN 1008. In a manner similar to the growth process illustrated in FIG. 10A, for the growth processes illustrated in FIGS. 10B and 10C, the interface 1014 of the p-type GaN 1012 is located at a distance from the initial regrowth interface 1016, i.e., is spatially separated by n-type GaN 1018, and the interface 1024 of the p-type GaN 1022 is located at a distance from the initial regrowth interface 1026, i.e., is spatially separated by n-type GaN 1028, respectively.

Thus, embodiments of the present invention contrast with conventional techniques utilizing MOCVD to form vertical FETs. During an MOCVD process, it is not feasible to grow n-type GaN, perform etching to form structures in the n-type GaN, and thereafter grow p-type GaN without breaking vacuum. As will be evident to one of skill in the art, breaking vacuum is problematic because the vacuum environment within a reactor or chamber is disrupted or terminated, thereby increasing contamination risks, increasing equipment or sample damage risks, and taking more time to re-establish the vacuum environment.

The method 500 also includes patterning the p-type GaN to form p-type gates (510). After the p-type GaN regrowth process is finished, the wafer will go through etch, lithography, and cleaning processes to form the gates and be prepared for applying the ohmic contacts to the source, gate, and drain. The gate and the source should generally be both accessible from the top.

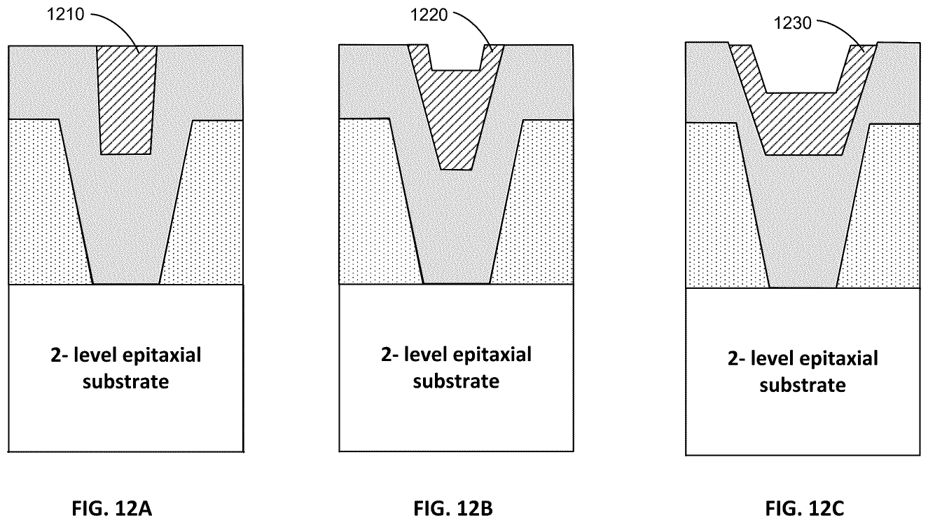

FIGS. 12A-12C are cross-sectional diagrams illustrating gate shapes according to embodiments of the present invention. As shown in FIGS. 12A-12C, the gates can have different shapes as illustrated by the three examples provided in these figures. In FIG. 12A, a gate 1210 with a planar top surface is illustrated. In FIG. 12B, a gate 1220 that is generally cylindrical with a small recess in the top surface is illustrated. In FIG. 12C, a gate 1230 that increases in lateral width as a function of height and has a large recess in the top surface is illustrated.

The method 500 further includes forming source, gate, and drain contacts (512). The formation of the source, gate, and drain contacts can be referred to as forming ohmic contacts. In some embodiments, the ohmic contacts are formed by a metal deposition process.

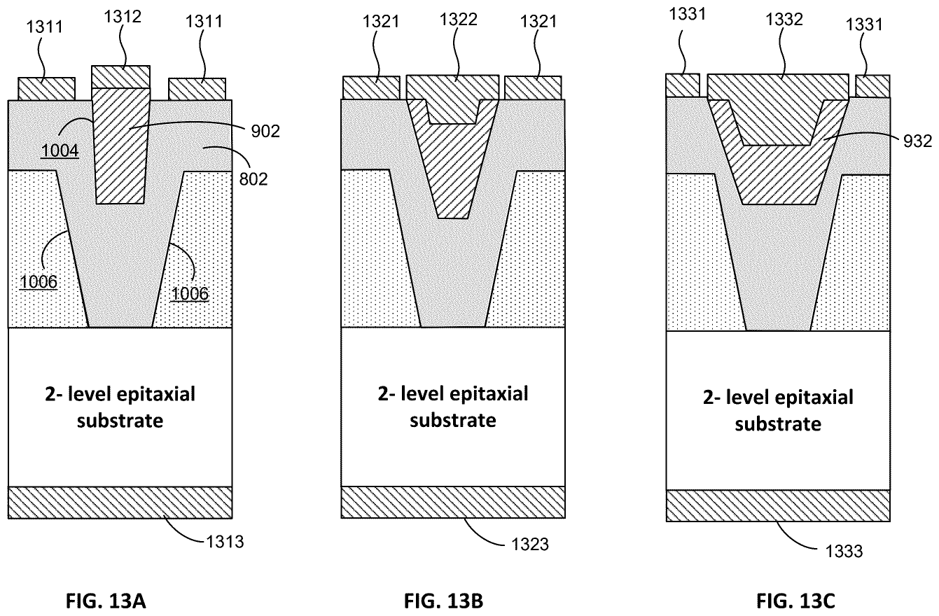

FIGS. 13A-13C are cross-sectional diagrams illustrating ohmic contacts according to embodiments of the present invention. In FIG. 13A, the ohmic contacts for the gate contact 1312, the source contact 1311, and the drain contact 1313 are illustrated. The ohmic contacts for the gate contact 1312, the source contact 1311, and the drain contact 1313 can include a variety of different metals and alloys used to connect to the n-type and p-type GaN material. In some embodiments, the p-type GaN regrowth process can include growth a p+ layer to facilitate formation of ohmic gate contacts. When a negative voltage is applied between the gate contact 1312, and the source contact, the depletion region extends into the n-type GaN 802 connected to the source. It is notable that the depletion region formed at the interface 1004 between the n-type channel formed by n-type GaN 802 and the p-type gate formed by p-type GaN 902 is located at a distance from the interface 1006 between the second GaN drift layer 1006 as discussed above. Because the interface 1004, also referred to as a junction, was formed in a vacuum environment during the MBE process, defects associated with breaking of vacuum are not present at interface 1004 (e.g., a silicon atom concentration of 1×10¹⁸ cm⁻³).

Referring to FIGS. 13B and 13C, gate contact 1322, source contact 1321, and drain contact 1323 are illustrated in FIG. 13B and gate contact 1332, source contact 1331, and drain contact 1333 are illustrated in FIG. 13C.

Moreover, embodiments of the present invention provide a high level of control of the shape of the gate and the gate contact. FIGS. 13A-13C illustrate ohmic contact formation (i.e., source, gate, and drain contacts) using the different gate shapes shown in FIGS. 12A-12C. For example, the gate formed by p-type GaN 932 illustrated in FIG. 13C has a wide gate with a gate contact 1332 positioned deep in the regrown gate structure, resulting in gradual decrease in the electric field and mitigation of edge effects. As another example, the gate formed by p-type GaN 902 illustrated in FIG. 13A will provide the lowest on-resistance. Thus, a suite of products ranging from high levels of gate control to low on-resistance are enabled by embodiments of the present invention. One of ordinary skill in the art would recognize many variations, modifications, and alternatives.

Generally, high-power transistors can be designed to operate in two different modes, depletion mode (d-mode) and enhancement mode (e-mode). If the channel conductivity is such that meaningful current flows from source to drain at zero gate bias, the device is d-mode. This mode is often referred to as “normally-on.” If the channel conductivity is such that no meaningful current flows from the source to drain at zero gate bias, the device is considered e-mode. This mode is often referred to as “normally-off.” Devices of either mode type can be achieved through judicious choice of doping levels and device dimensions.

A junction field effect transistor (JFET) is a common high-power transistor design that opens or closes the channel using the depletion region generated at the interface of an n-type and p-type material. A depletion region in a PN junction is a narrow area where mobile charge carriers (electrons and holes) have diffused away, leaving behind a region with only fixed ionized donor and acceptor atoms, creating an electric field across the junction. Essentially, it's a region depleted of free charge carriers due to diffusion of charges across the junction. When a bias is applied across the two materials and “N_{d}<<Nₐ” (meaning the doping concentration in the n-type region is much smaller than the p-type region), the depletion width is dependent on the relative permittivity of the semiconductor (εᵣ), the difference between the built in potential and the applied bias (φ_{bn}−V), the charge of an electron (q) and the doping of the n-type material N_{d} according to Eq.1

$$W = \sqrt{\frac{2 {ε}_{r} {ε}_{0} ( {φ}_{b n} - V )}{q {N}_{d}}} \qquad ( Eqn . 1 )$$

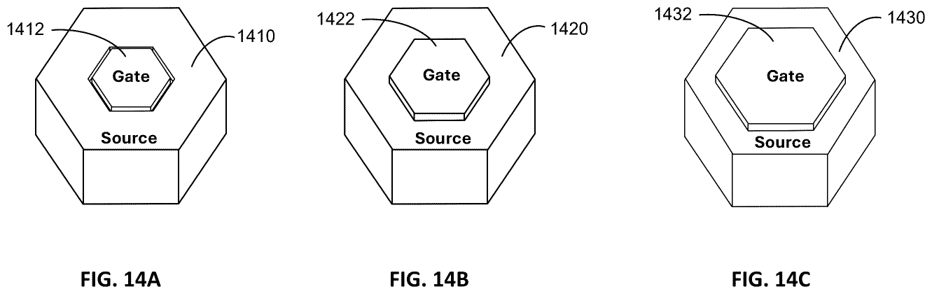

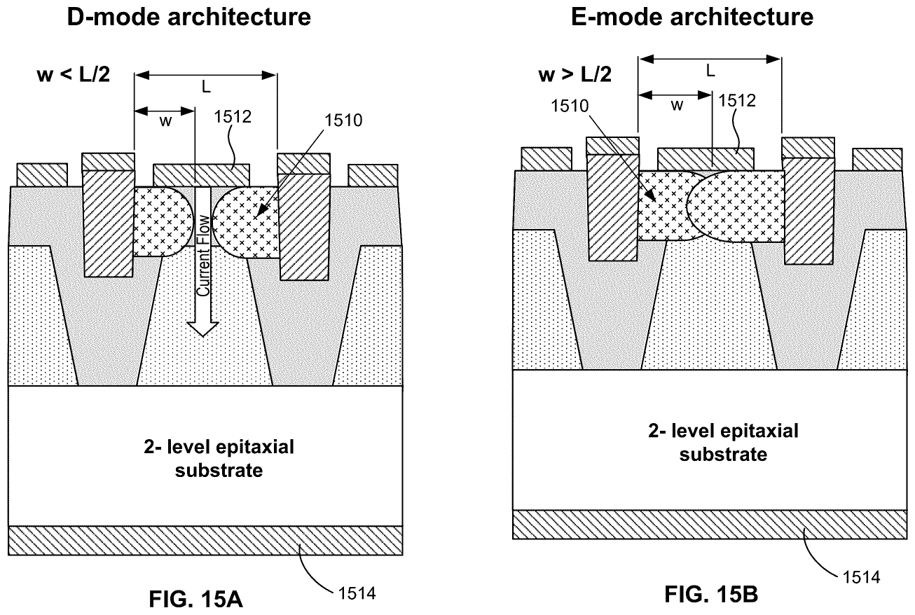

The funnel GaN FET is capable of producing both a d-mode and e-mode device. FIGS. 14-15 are diagrams illustrating the benefits of the funnel GaN FET structures as it pertains to the performance of d-mode or e-mode JFET devices and perspective views of three designs with different channel sizes according to embodiments of the present invention.

FIGS. 14A-14C are simplified perspective diagrams illustrated various designs for achieving different operational modes according to embodiments of the present invention. FIGS. 15A and 15B are simplified cross sectional diagrams illustrating operation of D-mode and e-mode JFET architectures, respectively, according to an embodiment of the present invention.

Referring to FIGS. 14A-14C, these simplified perspective diagrams illustrate three designs with different channel sizes according to various embodiments of the present invention. In FIG. 14A, the channel size corresponding to the source 1410 is large because the gate size corresponding to the gate 1412 is small. In FIG. 14C, the channel size corresponding to the source 1430 is small because the gate size corresponding to the gate 1432 is large. In FIG. 14B, an intermediate channel size corresponding to a channel formed by source 1420 having a medium size and the corresponding gate 1422 is illustrated compared to the channel sizes for the embodiments illustrated in FIGS. 14A and 14C.

Referring to FIG. 15A, for d-mode operation, successive p-layers are separated by a distance L such that L>2 W. At zero bias, the depletion regions 1510 do not overlap, and current can flow from source 1512 to drain 1514 terminals of the device. However, if a large enough negative bias is applied across the junction, the depletion region can expand sufficiently (L<2 W) so the depletion regions 1510 overlap and pinch-off the channel (i.e., no current flow). Referring to FIG. 15B, for e-mode operation of JFETs, successive p-layers are separated by a distance L such that L<2 W. At zero bias, the depletion regions 1510 overlap, and no current can flow from source 1512 to drain 1514 terminals. Under sufficient forward bias, the depletion region width decreases and allows current to flow from source to drain.

Referring to FIGS. 15A and 15B, a depletion region 1510 is formed between n-type and p-type materials depending on the carrier density of the doped regions. By choosing the correct doping for the p-type gate and n-type channel, it is possible to create a value of w such that 2w is greater than L. In that case, the depletion regions between the two gates overlaps and does not allow the current from the source to flow down to the drain. Such an operation would be an e-mode JFET as illustrated in FIG. 15B.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method comprising:
providing a two-level gallium nitride (GaN) epitaxial substrate comprising a first GaN drift layer characterized by a first doping concentration and a second GaN drift layer disposed on the first GaN drift layer and characterized by a second doping concentration higher than the first doping concentration;
forming a plurality of pedestals in the second GaN drift layer, wherein each of the plurality of pedestals is laterally separated by one of a plurality of funnels;
performing a channel regrowth process to regrow a plurality of n-type GaN channels, each of the plurality of n-type GaN channels being disposed in one of the plurality of funnels;
performing a gate regrowth process to regrow p-type GaN;
patterning the p-type GaN to form a plurality of p-type GaN gates, wherein each of the plurality of p-type GaN gates is disposed in one of the plurality of n-type GaN channels; and
forming source contacts to each of the plurality of n-type GaN channels, gate contacts to each of the plurality of p-type GaN gates, and a drain contact to the two-level GaN epitaxial substrate.

2. The method of claim 1 wherein each of the plurality of funnels is characterized by a funnel width and each of the plurality of n-type GaN channels is characterized by a channel width less than the funnel width.

3. The method of claim 1 wherein performing the channel regrowth process and performing the gate regrowth process are performed without breaking vacuum.

4. The method of claim 1 wherein performing the channel regrowth process and performing the gate regrowth process are performed in a Molecular Beam Epitaxy (MBE) system.

5. The method of claim 1 wherein performing the channel regrowth process and performing the gate regrowth process are performed at a growth temperature less than 800° C. and a V/III ratio less than 250.

6. The method of claim 1 wherein the first GaN drift layer comprises a first n-type GaN layer characterized by a first doping concentration and a second n-type GaN layer characterized by a second doping concentration higher than the first doping concentration.

7. A field effect transistor comprising:
a substrate;
a drift layer coupled to the substrate;
a funnel formed in the drift layer;
a channel extending into the funnel;
a gate extending into the channel;
a source contact electrically connected to the channel;
a gate contact electrically connected to the gate; and
a drain contact electrically connected to the substrate.

8. The field effect transistor of claim 7 wherein the drift layer comprises a first n-type GaN layer characterized by a first doping concentration and a second n-type GaN layer characterized by a second doping concentration higher than the first doping concentration.

9. The field effect transistor of claim 7 wherein:
the funnel is defined by a set of laterally spaced funnel/drift interfaces;
the gate is defined by a set of laterally spaced gate/funnel interfaces; and
the set of laterally spaced gate/funnel interfaces are laterally disposed between the set of laterally spaced funnel/drift interfaces.

10. The field effect transistor of claim 9 wherein one of the laterally spaced funnel/drift interfaces is oriented at a first angle to the substrate, one of the laterally spaced gate/funnel interfaces is oriented at a second angle to the substrate different than the first angle.

11. The field effect transistor of claim 9 wherein the set of laterally spaced funnel/drift interfaces are etch interfaces and set of laterally spaced gate/funnel interfaces are regrowth interfaces.

12. The field effect transistor of claim 7 wherein the funnel is characterized by a funnel width and the channel is characterized by a channel width less than the funnel width.

13. The field effect transistor of claim 7 wherein the gate comprises a p-type GaN region having a planar top surface.

14. A method of forming a two-level gallium nitride (GaN) epitaxial substrate, the method comprising:
ammonothermally growing a GaN substrate;
depositing a first GaN drift layer on the GaN substrate using a hydride vapor phase epitaxy (HVPE) process, wherein the first GaN drift layer is characterized by a first doping concentration; and
depositing a second GaN drift layer on the GaN substrate using the HVPE process, wherein the second GaN drift layer is characterized by a second doping concentration higher than the first doping concentration.

15. The method of claim 14 further comprising:
forming a plurality of pedestals in the second GaN drift layer, wherein each of the plurality of pedestals is laterally separated by one of a plurality of funnels;
performing a channel regrowth process to regrow a plurality of n-type GaN channels, each of the plurality of n-type GaN channels being disposed in one of the plurality of funnels;
performing a gate regrowth process to regrow p-type GaN;
patterning the p-type GaN to form a plurality of p-type GaN gates, wherein each of the plurality of p-type GaN gates is disposed in one of the plurality of n-type GaN channels; and
forming source contacts to each of the plurality of n-type GaN channels, gate contacts to each of the plurality of p-type GaN gates, and a drain contact to the two-level GaN epitaxial substrate.

16. The method of claim 15 wherein each of the plurality of funnels is characterized by a funnel width and each of the plurality of n-type GaN channels is characterized by a channel width less than the funnel width.

17. The method of claim 15 wherein performing the channel regrowth process and performing the gate regrowth process are performed without breaking vacuum.

18. The method of claim 15 wherein performing the channel regrowth process and performing the gate regrowth process are performed in a Molecular Beam Epitaxy (MBE) system.

19. The method of claim 18 wherein performing the channel regrowth process and performing the gate regrowth process are performed at a growth temperature less than 800° C. and a V/III ratio less than 250.
